(19) United States
(12) Patent Application Publication
(10) Pub. No.: US 2021/0296363 A1
(43) Pub. Date: Sep. 23, 2021

(54) ARRAY SUBSTRATE AND DISPLAY PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Shuai ZHOU, Shenzhen (CN); Yan XUE, Shenzhen (CN)

(73) Assignee: Shenzhen China Star Optoelectronics Semiconductor Display Technology Co., Ltd., Shenzhen, Guangdong (CN)

(21) Appl. No.: 16/980,397

(22) PCT Filed: May 26, 2020
(86) PCT No.: PCT/CN2020/092280

§ 371 Date: Sep. 13, 2020

(30) Foreign Application Priority Data
Mar. 18, 2020 (CN) 202010190331.1

(51) Int. Cl. H01L 27/12

(52) U.S. Cl. CPC H01L 27/124

(57) ABSTRACT

An array substrate and a display device are disclosed. The array substrate includes a substrate, a first gate line, a second gate line, via holes, and a first metal line. By providing the via holes in a non-display area, a pixel space in a display area occupied by the via holes can be prevented, which is beneficial to increase storage capacitance of the pixel, and the capacitance being increased takes up about 25% of the storage capacitance of the pixel. There is no need to change original internal design of the pixel, causing little influence on internal design space of the pixel, being adapted to high PPI pixel design, simple in pixel design, easy to be implemented, and universally compatible.

### BACKGROUND OF INVENTION

### 1. Field of Invention

The present invention relates to a technical field of displays, and particularly to, an array substrate and a display panel.

### 2. Related Art

Compared with amorphous silicon (a-Si) thin-film transistors (TFTs) and low-temperature polysilicon (LTPS) thin-film transistors, oxide thin-film transistors having characteristics, such as higher mobility, lower process temperature, and good uniformity, have been widely used in large-sized organic light-emitting diodes (OLEDs). At present, high refresh frequency, gate driver on array (GOA) narrow frame, flexibility, etc. have gradually become main developing directions of OLED panels. Therefore, requirements for mobility and stability of TFTs are gradually increasing.

Using dual-gate structure is an important way to improve the mobility and stability of TFTs. Compared with a single-gate TFT, two gates of a dual-gate TFT are distributed on two sides of an oxide, and channels are formed on the two sides of a semiconductor. That is, the dual-gate TFT has one more channel than the single-gate TFT. Therefore, more carriers are produced, which helps to improve the mobility and stability of TFTs.

Currently, dual-gate structures are mainly classified into two types: one is that a bottom gate is switched to a top gate through a metal component to form a dual-gate structure; and the other one is that a bottom gate is switched to a dual-gate structure by being connected to a source electrode of a TFT through a metal component. Both the two types are required to provide switching holes for forming dual gates. As shown in FIG. 1, in order to meet demands for high pixel per inch (PPI) panels, size of pixels is gradually reduced, and design space inside the pixels is getting closer and close. Metal switching holes (annotated by a frame in FIG. 1) formed inside a pixel occupy design space of TFTs and storage capacitance in the pixel.

### SUMMARY OF INVENTION

An object of the present invention is to provide an array substrate including via holes provided on two sides of a display area for a first gate line and a second gate line, so that adversely effects caused by the via holes in the pixel can be prevented.

The present invention provides an array substrate, comprising a substrate comprising a display area and a non-display area, wherein each of two sides of the display area is provided with a non-display area; at least a first gate line disposed on the substrate and extending from the non-display area on one of the two sides of the display area to the non-display area on the other side of the display area; at least a second gate line correspondingly disposed above the first gate line, wherein an insulating layer is disposed between the second gate line and the first gate line; at least two via holes disposed on the two sides of the display area and extending through the insulating layer, respectively, and configured to expose parts of the first gate line and the second gate line; and a first metal line provided in the via holes and configured to connect the first gate line to the second gate line.

Further, the insulating layer comprises a first insulating layer disposed on the first gate line and the substrate; a second insulating layer disposed on the first insulating layer and corresponding to the second gate line; a third insulating layer disposed on the first insulating layer and the second gate line; and a fourth insulting layer disposed on the third insulating layer.

Further, the via holes comprise a groove and a through hole, the groove is defined in the third insulating layer and is recessed downward to a surface of the second gate line, and the through hole extends through the third insulating layer and a part of the first insulating layer to a surface of the first gate line.

Further, the first metal line is disposed on the fourth insulating layer, one end of the first metal line is connected to the second gate line through the groove, and the other end is connected to the first gate line over the through hole.

Further, the array substrate further comprises a semiconductor layer disposed in the display area and situated between the first gate line and the second gate line and corresponding to the second gate line.

Further, the first gate line and the second gate line are connected in parallel.

Further, the first gate line has a width greater than that of the second gate line, and the second gate line has a projection area projected on the substrate and overlapping the first gate line in the display area.

Further, the first gate line is switched to the second gate line by the first metal line in the via holes prior to entering the display area, or the second gate line is switched to the first gate line by the first metal line in the via holes prior to entering the display area.

Further, the first gate line is made of a material comprising aluminum, copper, or a metal alloy material; and/or the second gate line is made of a material comprising aluminum, copper, or a metal alloy material; and/or the first metal line is made of a material comprising aluminum, copper, or a metal alloy material.

The present invention further provides a display panel comprising the above-mentioned array substrate.

The present invention has advantageous effects as follows: the present invention provides an array substrate including via holes provided on two sides of a display area for a first gate line and a second gate line, so that a dual-gate structure is formed, thereby a pixel space in the display area occupied by the via holes can be prevented, which is beneficial to increase storage capacitance of the pixel.

### BRIEF DESCRIPTION OF DRAWINGS

FIG. 1 is a plan view of a pixel structure in prior art.

FIG. 2 is a plan view of an array substrate provided by the present invention.

FIG. 3 is a cross-sectional view of a via hole in a non-display area of FIG. 2.

FIG. 4 is a plan view of a pixel structure in a display area provided by the present invention.

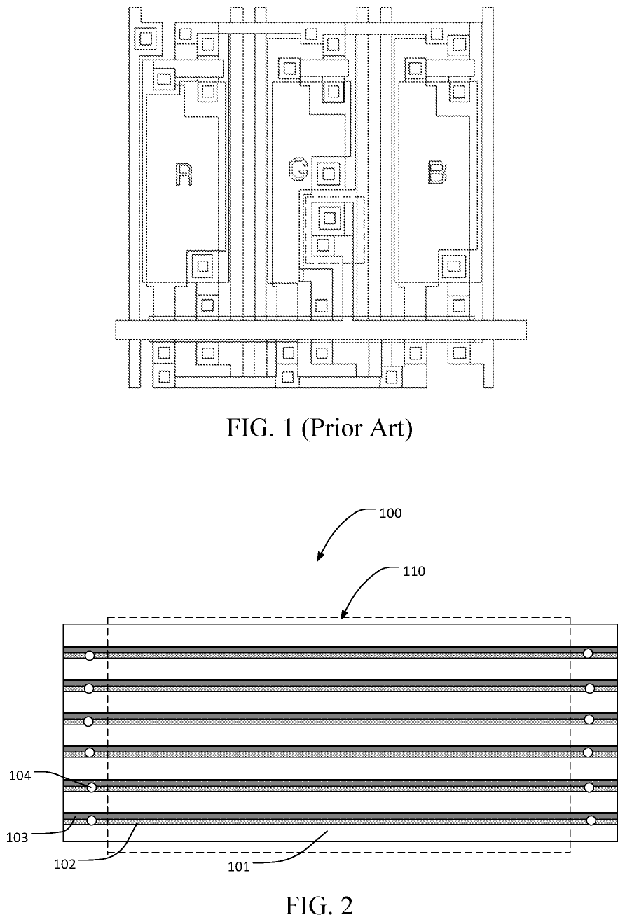

### DESCRIPTION OF PREFERRED EMBODIMENTS

The technical solutions in the embodiments of the present application will be clearly and completely described in the following with reference to the accompanying drawings in the embodiments. Apparently, the embodiments as described are only a part, but not all, of the embodiments of the present application. Based on the embodiments in the present application, all other embodiments obtained by those skilled in the art without creative efforts shall be within the scope of the present application.

In the description of the present invention, it is to be understood that the term “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” and the like indicates orientation or the orientation or positional relationship based on the positional relationship shown in the drawings, for convenience of description only and the present invention is to simplify the description, but does not indicate or imply that the device or element referred to must have a particular orientation in a particular orientation construction and operation, and therefore not be construed as limiting the present invention. Moreover, the terms “first” and “second” and the like are used for descriptive purposes only and are not to be construed as indicating or implying relative importance. Thus, features defining “first” or “second” may include one or more of the described features either explicitly or implicitly. In the description of the present invention, the meaning of “a plurality” is two or more unless specifically and specifically defined otherwise.

In the present invention, unless otherwise explicitly specified or limited, the terms “mounted”, “linked”, “connected”, and like terms are to be broadly understood. For example, it may be a fixed connection, a detachably connection, or an integrally connection, or may be a mechanical connection, electrically connection, or a directly connection. Alternatively, it can also be connected indirectly through intervening structures, or may be interaction between the two internal communicating elements or two elements. Those of ordinary skill in the art, to be understood that the specific meanings in the present invention in accordance with specific circumstances.

In the present invention, unless otherwise explicitly specified or limited, the terms “mounted”, “linked”, “connected”, and like terms are to be broadly understood. For example, it may be a fixed connection, a detachably connection, or an integrally connection, or may be a mechanical connection, electrically connection, or a directly connection. Alternatively, it can also be connected indirectly through intervening structures, or may be interaction between the two internal communicating elements or two elements. Those of ordinary skill in the art, to be understood that the specific meanings in the present invention in accordance with specific circumstances.

The following disclosure provides many different embodiments or examples to achieve different structures of the present invention. To simplify the disclosure of the present invention, the components and configuration of specific examples are described hereinafter. Of course, they are only illustrative, and are not intended to limit the present invention. Further, the present disclosure may repeat reference numerals in different embodiments and/or the reference letters. This repetition is for the purpose of simplicity and clarity, and does not indicate a relationship between the various embodiments and/or set in question. Further, the present invention provides various specific examples of materials and processes, but one of ordinary skill in the art may be appreciated that other processes and applications and/or other materials.

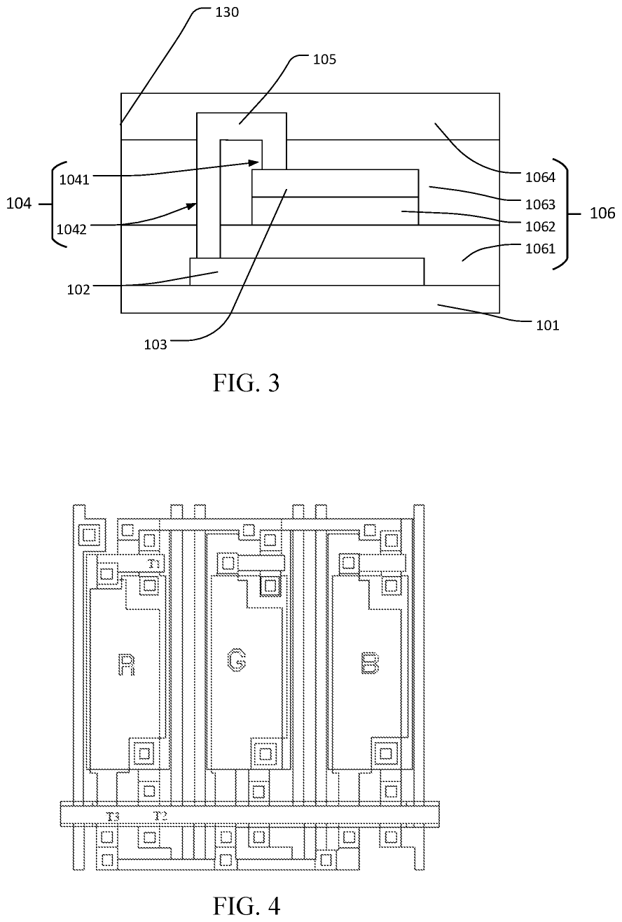

As shown in FIGS. 2 and 3, the present invention provides an array substrate 100 including a substrate 101, a first gate line 102, a second gate line 103, a connecting hole 104, and a first metal line 105.

The substrate 101 includes a display area 110 and a non-display area, wherein each of two sides of the display area 110 is provided with a non-display area.

The first gate line 102 is longitudinally disposed on the substrate 101, a number of the first gate line 102 is at least one, and the first gate line 102 extends from the non-display area on one of the two sides of the display area 110 to the non-display area on the other side of the display area 110. When there are more than two first gate lines 102, they are arranged in parallel with each other.

The second gate line 103 is correspondingly disposed above the first gate line 102. At least an insulating layer 106 is disposed between the second gate line 103 and the first gate line 102.

Each of the first gate lines 102 is corresponding to two via holes 104 which are disposed on the two sides of the display area 110 and extend through the insulating layer 106, respectively, and are configured to expose parts of the first gate line 102 and the second gate line 103.

The first metal line 105 is provided in the via holes 104 and is configured to connect the first gate line 102 to the second gate line 103.

In one embodiment, the insulating layer 106 includes a first insulating layer 1061, a second insulating layer 1062, a third insulating layer 1063, and a fourth insulating layer 1064.

The first insulating layer 1061 is disposed on the first gate line 102 and the substrate 101. The second insulating layer 1062 is disposed on the first insulating layer 1061 and corresponds to the second gate line 103. The third insulating layer 1063 is disposed on the first insulating layer 1061 and the second gate line 103. The fourth insulating layer 1064 is disposed on the third insulating layer 1063.

In one embodiment, the via holes 104 include a groove 1041 and a through hole 1042. The groove 1041 is defined in the third insulating layer 1063 and is recessed downward to a surface of the second gate line 103, and the through hole 1042 extends through the third insulating layer 1063 and a part of the first insulating layer 1061 to a surface of the first gate line 102.

The first metal line 105 is disposed on the fourth insulating layer 1064, one end of the first metal line 105 is connected to the second gate line 103 through the groove 1041, and the other end is connected to the first gate line 102 over the through hole 1042.

In one embodiment, a semiconductor layer is disposed in the display area 110 and situated between the first gate line 102 and the second gate line 103 and corresponding to the second gate line 103, so that a subpixel structure is formed as shown in FIG. 4. In each subpixel structure, a storage capacitor is formed in an effective area between the first gate line 102 and the second gate line 103.

The first gate line 102 and the second gate line 103 are connected in parallel, thereby reducing resistance of an entire gate line and facilitating decrease in RC (resistor-capacitor) loading of the gate line.

The via holes 104 of the present invention are disposed in the non-display area so that space of a pixel of the display area 110 is not occupied by the via holes 104 and therefore is beneficial to increase storage capacitance of the pixel. The capacitance being increased takes up about 25% of the storage capacitance of the pixel, so there is no need to change original internal design of the pixel, thereby causing little influence on internal design space of the pixel, being adapted to high PPI (pixel per inch) pixel design, being easy to be implemented, and being universally compatible.

The first gate line 102 has a width greater than that of the second gate line 103. The second gate line 103 has a projection area projected on the substrate 101 and overlapping the first gate line 102 in the display area 110. As a result, the two gate lines of the present invention are configured in a parallel and face-to-face arrangement in an up-to-bottom direction, which avoids a newly introduced gate line occupying the pixel design space and saves the pixel design space.

The first gate line 102 is switched to the second gate line 103 by the first metal line 105 in the via holes 104 prior to entering the display area 110, or the second gate line 103 is switched to the first gate line 102 by the first metal line 105 in the via holes 104 prior to entering the display area 110.

The first gate line 102 is made of a material including aluminum, copper, or a metal alloy material; and/or the second gate line 103 is made of a material including aluminum, copper, or a metal alloy material; and/or the first metal line 105 is made of a material including aluminum, copper, or a metal alloy material.

The present invention provides an array substrate 100 including a first gate line 102 and a second gate line 103 disposed on two sides of the display area 110 through the via holes 104. Prior to entering the display area 110, the first gate line 102 is switched to the second gate line 103 by the first metal line 105 in the via holes 104; alternatively, prior to entering the display area 110, the second gate line 103 is switched to the first gate line 102 by the first metal line 105 in the via holes 104, so that a dual-gate structure of a pixel is formed. Therefore, a pixel space of the display area 110 occupied by the via holes 104 can be prevented, which is beneficial to increase storage capacitance of the pixel, and the capacitance being increased takes up about 25% of the storage capacitance of the pixel.

Additionally, gate line wiring in the pixel becomes simpler, reducing parasitic capacitance between gate lines and other layers. Furthermore, resistance of the gate lines is further reduced because of a parallel structure of upper and lower gate lines formed by via holes 104 provided in each of two ends of the two gate lines.

TABLE 1
Comparison between two types of dual-gate structures

| | Dual-gate via holes | Dual-gate via holes |
|---|---|---|
| | formed in an | formed inside |
| Item | outside area | a pixel |
| Gate resistance (kΩ) | 1.90 | 2.56 |
| Gate C loading (pF) | 576.7 | 600.5 |
| Pixel G storage capacitance | 0.49 | 0.34 |
| (pF) | | |

Accordingly, compared with designing the dual-gate via holes 104 in the pixel, configuring the dual-gate via holes 104 at a periphery of a panel helps to reduce the RC loading of the gate lines, and also helps to increase storage capacitance of the pixel.

The present invention further provides a display panel including the array substrate 100.

By providing the via holes 104 of the first gate line 102 and the second gate line 103 on two sides of the display area 110, prior to entering the display area 110, the first gate line 102 is switched to the second gate line 103 by the first metal line 105 provided in the via holes 104; alternatively, prior to entering the display area 110, the second gate line 103 is switched to the first gate line 102 by the first metal line 105 provided in the via holes 104, so that a dual-gate structure of a pixel is formed. Therefore, the pixel space in the display area 110 occupied by the via holes 104 can be prevented, which is beneficial to increase storage capacitance of the pixel, and the capacitance being increased takes up about 25% of the storage capacitance of the pixel.

Additionally, gate line wiring in the pixel becomes simpler, reducing parasitic capacitance between gate lines and other layers. Furthermore, resistance of the gate lines is further reduced because of a parallel structure of upper and lower gate lines formed by via holes 104 provided in each of two ends of the two gate lines.

According to the present invention, there is no need to change original internal design of the pixel, thereby causing little influence on internal design space of the pixel, and being adapted to high PPI pixel design. The present invention is simple in design, easy to be implemented, and universally compatible.

It can be understood that for those of ordinary skill in the art, equivalent replacements or changes can be made according to the technical solutions and inventive concepts of the present application, and all such changes or replacements should fall within the protection scope of the claims appended to the present application.

What is claimed is:

1. An array substrate, comprising:
a substrate comprising a display area and a non-display area, wherein each of two sides of the display area is provided with a non-display area;
at least a first gate line disposed on the substrate and extending from the non-display area on one of the two sides of the display area to the non-display area on the other side of the display area;
at least a second gate line correspondingly disposed above the first gate line, wherein an insulating layer is disposed between the second gate line and the first gate line;
at least two via holes disposed on the two sides of the display area and extending through the insulating layer, respectively, and configured to expose parts of the first gate line and the second gate line; and
a first metal line provided in the via holes and configured to connect the first gate line to the second gate line.

2. The array substrate of claim 1, wherein the insulating layer comprises:
a first insulating layer disposed on the first gate line and the substrate;
a second insulating layer disposed on the first insulating layer and corresponding to the second gate line;
a third insulating layer disposed on the first insulating layer and the second gate line; and
a fourth insulting layer disposed on the third insulating layer.

3. The array substrate of claim 2, wherein the via holes comprise a groove and a through hole, the groove is defined in the third insulating layer and is recessed downward to a surface of the second gate line, and the through hole extends through the third insulating layer and a part of the first insulating layer to a surface of the first gate line.

4. The array substrate of claim 3, wherein the first metal line is disposed on the fourth insulating layer, one end of the first metal line is connected to the second gate line through the groove, and the other end is connected to the first gate line over the through hole.

5. The array substrate of claim 2, further comprising a semiconductor layer disposed in the display area and situated between the first gate line and the second gate line and corresponding to the second gate line.

6. The array substrate of claim 3, wherein the first gate line and the second gate line are connected in parallel.

7. The array substrate of claim 1, wherein the first gate line has a width greater than that of the second gate line, and the second gate line has a projection area projected on the substrate and overlapping the first gate line in the display area.

8. The array substrate of claim 1, wherein the first gate line is switched to the second gate line by the first metal line in the via holes prior to entering the display area, or the second gate line is switched to the first gate line by the first metal line in the via holes prior to entering the display area.

9. The array substrate of claim 1, wherein the first gate line is made of a material comprising aluminum, copper, or a metal alloy material; and/or the second gate line is made of a material comprising aluminum, copper, or a metal alloy material; and/or the first metal line is made of a material comprising aluminum, copper, or a metal alloy material.

10. A display panel, comprising the array substrate of claim 1.
